(19) United States
(12) Patent Application Publication
(10) Pub. No.: US 2007/0147491 A1
(43) Pub. Date: Jun. 28, 2007

(54) Transmitter equalization

(75) Inventors: Bryan K. Casper, Hillsboro, OR (US); James E. Jaussi, Hillsboro, OR (US)

Correspondence Address: INTEL CORPORATION;c/o INTELLEVATE, LLC, P.O. BOX 52050, MINNEAPOLIS, MN, 55402, US

(73) Assignee: Intel Corporation

(21) Appl. No.: 11/317,162

(22) Filed: Dec. 22, 2005

(51) Int. Cl. H03K 5/159

(52) U.S. Cl. 375/232

(57) ABSTRACT

According to embodiments of the subject matter disclosed in this application, transmit equalization, systematic jitter correction, and jitter injection may be achieved through a lookup table transmitter equalizer. The equalizer may be a multiple-way interleaving equalizer, with each interleaved section having its own lookup table. Entries in each lookup table may be modified to correct systematic jitters occurring in the received signal. Additionally, random errors may be injected to each lookup table. Injected errors are converted to both amplitude and phase modulation across a channel. By measuring the signal at the receiver, the characteristics of the transmission line may be obtained.

### BACKGROUND

1. Field

This disclosure relates generally to semiconductor devices, and, more specifically but not exclusively, to input/output (“I/O”) devices with transmitter equalization.

2. Description

Integrated circuits (“ICs”) typically communicate with one another and with other devices using conductive transmission lines (or channels). The conductive transmission lines may take the form of traces on a printed wiring board, cables, or the like. ICs typically include interface circuits (e.g., I/O interface circuits) that include drivers and receivers coupled to the conductive transmission lines. For example, an interface circuit may have a signal driver to drive electrical signals on one transmission line, and a signal receiver to receive different electrical signals from a second transmission line. Also for example, an interface circuit may have both a signal driver and a signal receiver coupled to the same transmission line for bidirectional communication using a single transmission line.

In a digital system, digital bits, or “symbols,” are transmitted on conductive transmission lines. A symbol may represent one or more digital bits of information. As the speed of communication increases, the symbols are transmitted faster, and the time distance between adjacent symbols becomes smaller. Signal drivers transmit symbols on conductive transmission lines, and signal receivers receive symbols on the conductive transmission lines.

An “ideal” transmission line is a transmission line that conducts an electrical signal from one end to the other without distortion. In practice, perfectly ideal transmission lines do not exist. Every transmission line has a finite bandwidth, and for signal bandwidths that are comparable to or exceed the transmission line (channel) bandwidth, distortion will occur to the signal at the receiver side. As a result, signals that are driven onto one end of conductive transmission lines emerge with varying amounts of distortion at the other end of the transmission line. As the communication speed increases, the distortion increases. The distortion from one symbol may spread into an adjacent symbol and cause the adjacent symbol to be received incorrectly. This phenomenon is referred to as inter-symbol interference (“ISI”).

A common way to address ISI is through the use of equalization. Equalization can be applied at the transmitter, the receiver, or both. Transmitter equalization (often called pre-emphasis or de-emphasis) compensates for loss by pre-processing the signal before transmission, for example, by generating over-drive signals to boost higher frequency components of the signal. Transmitter equalization may be realized using a finite impulse response (“FIR”) filter in a form of a sum of a number of weighted delays. Weights of delays with different orders in the FIR filter are also called coefficients. For example, an FIR filter, f(z)=c₀+c₁*z⁻¹+c₂*z⁻²+c₃*z⁻³, has coefficients {c₀, c₁, c₂, c₃}. Coefficients of an FIR filter may be determined by a number of different ways. For example, a least means square (“LMS”) algorithm may be used to adaptively set coefficients for an FIR filter so that the resulting transmitter equalization may reflect real-time changes on the transmission line. In one embodiment, an FIR-based equalizer may be implemented by using a lookup table.

ISI not only causes magnitude distortion to signals, but also introduces systematic jitter in the signals. In addition to ISI, other factors (e.g., pattern-dependent clock drift and digital regenerator) can also cause systematic jitter. Systematic jitter can accumulate and lead to system instability. While transmitter equalization may be helpful in correcting systematic jitter caused by ISI, it is less helpful in correcting systematic jitter caused by other factors. Moreover, it is sometimes necessary to test and validate a transmission line so that a transmitter/receiver may be designed to accommodate characteristics of the transmission line.

For the reasons stated above, and for other reasons stated below which will become apparent to those skilled in the art upon reading and understanding the present application, it is desirable for alternate transmitter circuits that can not only address ISI but also address other issues such as systematic jitter and transmission line testing and validation.

### BRIEF DESCRIPTION OF THE DRAWINGS

The features and advantages of the disclosed subject matter will become apparent from the following detailed description of the subject matter in which:

FIG. 1 is a block diagram illustrating a digital system including a transmit equalizer;

FIG. 2 shows an example FIR-based 2-tap equalizer;

FIGS. 3A and 3B illustrate an example lookup table based implementation of a transmit equalizer;

FIGS. 4A and 4B illustrate an example lookup table equalizer that enables systematic jitter correction and jitter injection based testing and characterization of a transmission line;

FIG. 5 shows an example two-way interleaving lookup table equalizer for transmit equalization, systematic jitter correction, and jitter injection;

FIG. 6 shows an example four-way interleaving equalization system for transmit equalization, systematic jitter correction, and jitter injection;

FIG. 7 is a flowchart illustrating an example process for systematic jitter correction using a lookup table equalizer;

FIG. 8 shows example lookup tables with entry values obtained by using an adaptive method in a two-way interleaving lookup table equalizer;

FIG. 9 shows one example of modifying entries in lookup tables of a two-way interleaving lookup table equalizer to correct for systematic jitters;

FIG. 10 is a flowchart illustrating an example process for jitter injection based testing and characterization of a transmission line; and

FIG. 11 is a block diagram of a computer system with at least one lookup table equalizer for transmit equalization, system jitter correction, and jitter injection.

### DETAILED DESCRIPTION

According to embodiments of the subject matter disclosed in this application, transmit equalization, systematic jitter correction, and jitter injection may be achieved through a lookup table transmitter equalizer. The equalizer may be a multiple-way (e.g., 2-way, 4-way, etc.) interleaving equalizer, with each interleaved section having its own lookup table. Contents of all the lookup tables of all the interleaved sections may be set up by using an adaptive method (e.g., an LMS-based adaptive approach) to achieve optimal equalization effects. Afterwards, each lookup table may be subject to a scheme of content corrections. Content correction schemes are designed to correct systematic jitter occurring in the received signal. Different correction schemes may be applied to different lookup tables to correct errors that may be caused by a serializer.

In other embodiments, each interleaved section may have its own lookup table or share one lookup table. Contents of all the lookup tables of all the interleaved sections may be set up by using an adaptive method to achieve optimal equalization effects. Afterwards, random errors may be injected to each lookup table. Injected errors are converted to both amplitude and phase modulation across a lossy transmission line. By measuring the signal at the receiver, the characteristics of the transmission line may be obtained.

Reference in the specification to “one embodiment” or “an embodiment” of the disclosed subject matter means that a particular feature, structure or characteristic described in connection with the embodiment is included in at least one embodiment of the disclosed subject matter. Thus, the appearances of the phrase “in one embodiment” appearing in various places throughout the specification are not necessarily all referring to the same embodiment.

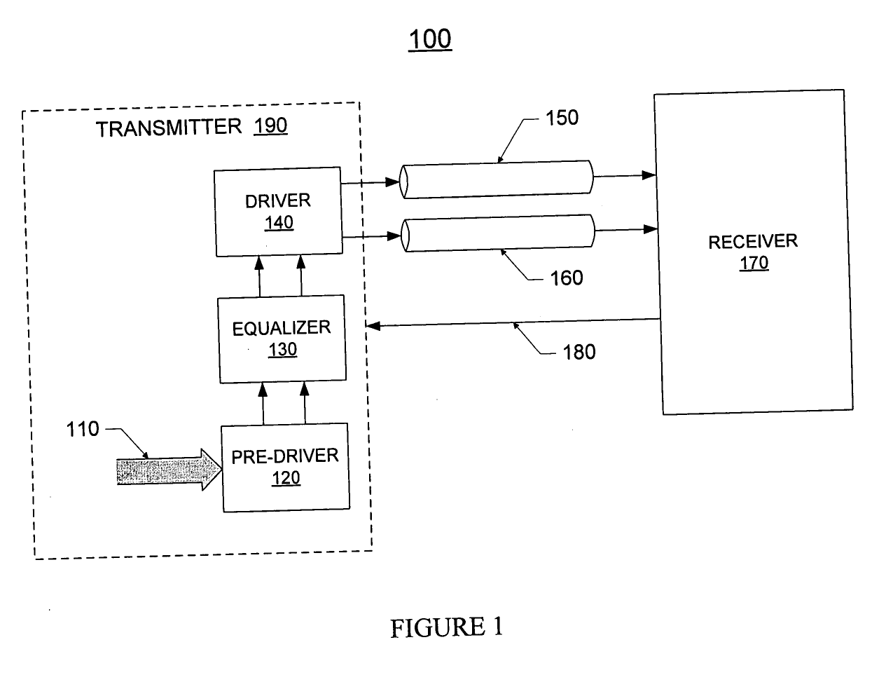

FIG. 1 is a block diagram illustrating a digital system 100 that includes a transmit equalizer. Digital system 100 includes a transmitter 190 and a receiver 170 connected by transmission lines (links) (e.g., link 150 and link 160). The transmitter includes a pre-driver 120, an equalizer 130, and a driver 140. The transmitter may also include a core logic (not shown in the figure) to generate a base-band signal 110 containing voice, data, or other information to be transmitted to the receiver. The pre-driver modulates the base-band signal on a carrier frequency. The driver may perform switching operations for controlling the transmission of the modulated signal along one or more of the links. The links may be lossy transmission lines, which may be traces on a printed wiring board, cables, etc.

Equalizer 130 may pre-emphasize the high frequency components or de-emphasize the low frequency components of the modulated signal using an FIR filter, for example, f(z)=c₀+c₁*z⁻¹+c₂*z⁻²+c₃*z⁻³. In this example, the equalizer is a 4-tap equalizer with tap weights or equalization coefficients being {c₀, c₁, c₂, c₃}. One of the challenges of any equalization architecture is setting the equalization coefficients. In a typical backplane environment with substantial channel-to-channel (or link-to-link) variations, there is no simple set of coefficient settings that will work for all channels. Typically an adaptation method is used to simultaneously determine the optimum solution for each of the equalization coefficients. For example, an LMS-based adaptation approach may be used to adapt the equalization coefficients based on feedback information from receiver 170. The feedback information may be passed to the transmitter through a loop-back channel 180.

The equalizer may include a memory to store tap coefficients. Alternatively, the equalizer may instead have a lookup table to store outputs for all possible data sequences based on the equalization coefficients. Using the above 4-tap equalizer example, the lookup table would contain FIR outputs for all 16 possible sequences of 4 digit signal segments. Lookup table based equalization is described in more detail below. In addition to performing equalization, a lookup table equalizer may also be used for systematic jitter correction and jitter injection.

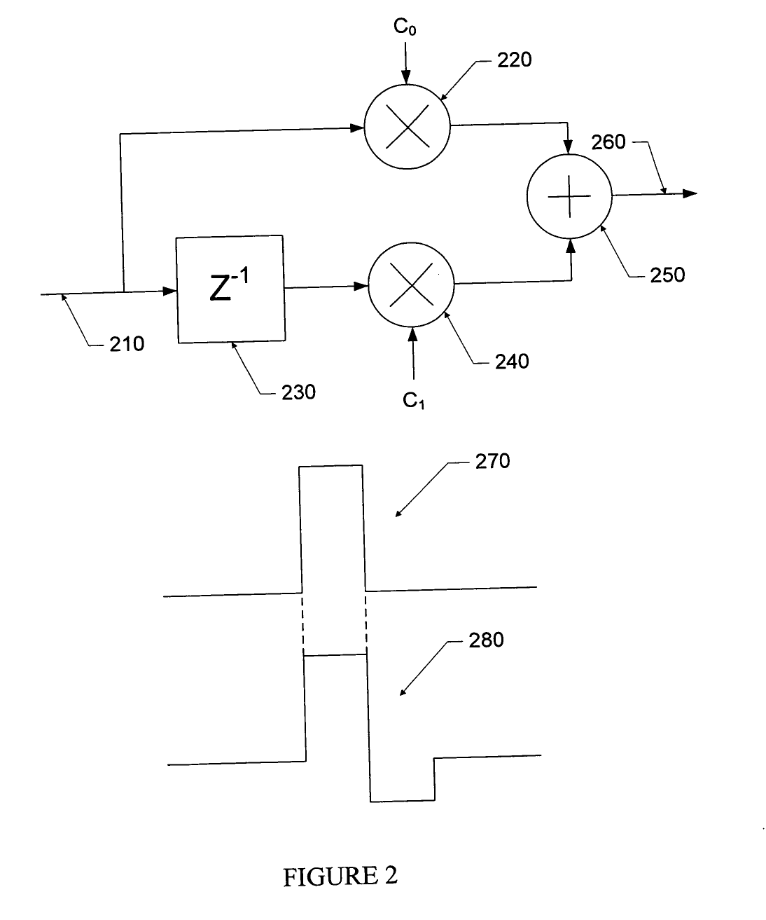

FIG. 2 shows an example FIR-based 2-tap equalizer that may be used in a transmitter such as the one shown in FIG. 1. In this figure, the equalizer may be expressed as, f(z)=c₀+c₁*z⁻¹, with equalization coefficients c₀ and c₁. The equalizer includes two multipliers 220 and 240, delay logic 230, and a summer circuit 250. Input data 210 is multiplied by coefficient c₀ via multiplier 220. Additionally, the input data is first delayed by one clock cycle through the delay logic and then is multiplied by coefficient c₁ via multiplier 240. The summer circuit adds outputs of the two multipliers to produce an output of the equalizer. FIG. 2 also shows a sample input signal 270 and its corresponding output 280 from the equalizer. It can be seen that the equalizer de-emphasizes the low frequency component of signal 270 while pre-emphasizing the high frequency component of signal 270.

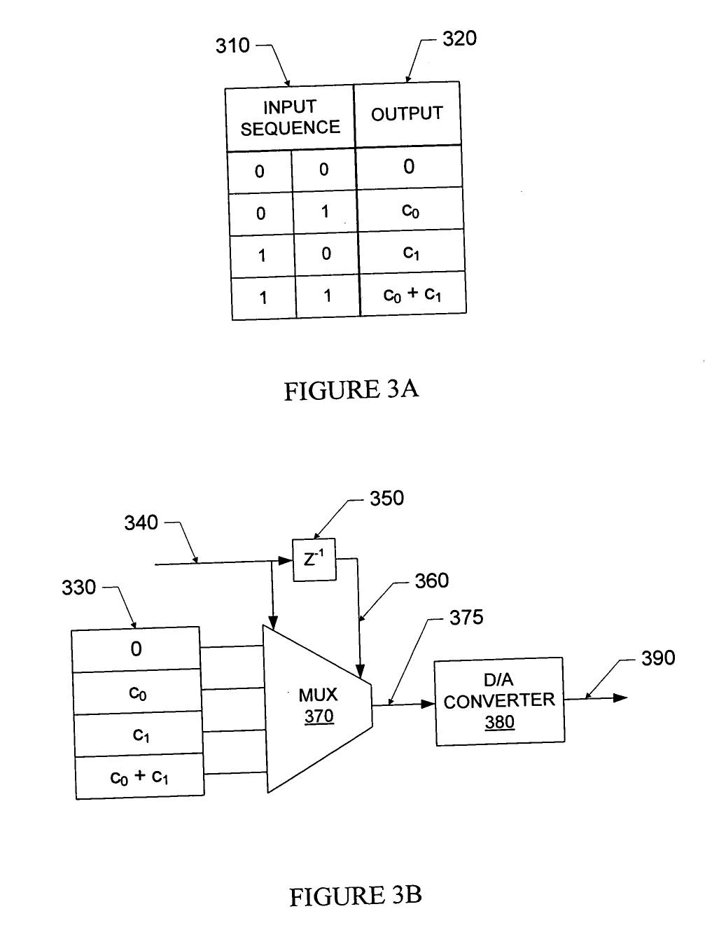

FIGS. 3A and 3B illustrate an example 2-tap lookup table based equalizer. FIG. 3A is a table showing outputs of the equalizer of all possible input data sequences of a 2 digit signal segment. Column 310 of the table lists all four possible data sequences, and column 320 shows outputs of the 2-tap equalizer (i.e., f(z)=c₀+c₁*z⁻¹) of all possible input sequences. FIG. 3B shows an example circuit implementation of the example 2-tap lookup table equalizer. The example circuit implementation includes a storage device 330, a multiplexer 370, delay logic 350 and an optional digital to analog (“D/A”) converter 390. The storage device may include a register file to store the lookup table, which has four entries, each corresponding to one output as shown in the table of FIG. 3A. The delay logic 350 shifts input data 340 by one bit. The shifted bit 360 and the current bit enable the multiplexer to select a corresponding entry in the lookup table. The D/A converter may convert the output of the multiplexer to analog form if required by the transmission lines.

The equalization coefficients may be obtained through adaptive training. Example adaptive training methods of equalization coefficients using a conditional update sign-sign LMS algorithm, which are disclosed in U.S. patent application Ser. No. 10/660,228, filed on Sep. 10, 2003 (incorporated by reference herein), could be used.

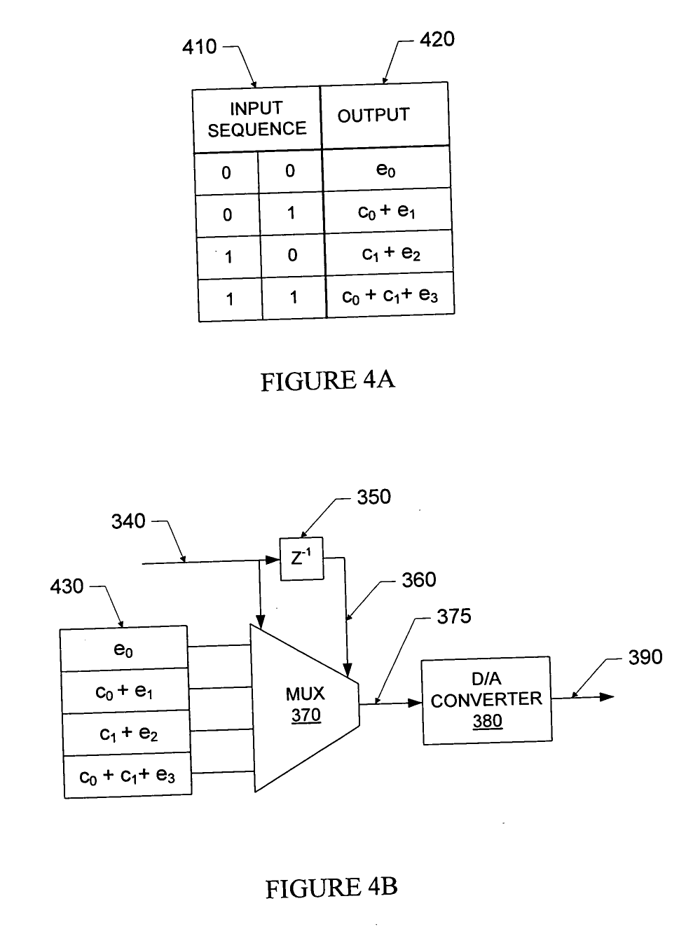

FIGS. 4A and 4B illustrate an example lookup table equalizer that enables systematic jitter correction and jitter injection based testing and characterization of a channel. FIG. 4A is a table showing that corrections can be made to each entry of the lookup table based on receiver feedback. Column 410 of the table is the same as column 310 of the table shown in FIG. 3A. Entries in column 420 of the table are obtained by adding corrections based on the receiver feedback. Data received at the receiver may contain systematic jitters, which may be caused by factors such as ISI, pattern-dependent clock drift, and digital regenerators. Pattern-dependent clock drift is caused by prolonged runs of identical bits. Since the clock-recovery circuitry does not regain fresh transitions with which to synchronize itself, it can drift towards the natural (resonant) frequency of the circuit. Regenerator characteristics vary with temperature and the aging of components and therefore affect all data passing through them in the same way over a given time period.

Systematic jitters caused by factors such as pattern-dependent clock shift and digital regenerators are not easily corrected by a lookup table equalizer with coefficients obtained through adaptive training. By adding directly to lookup table entries corrections based on information regarding systematic jitter obtained from the received data, systematic jitter may be corrected. Additionally, random errors may be added to each entry of the lookup table to inject jitters to a channel for the purpose of testing and characterization of the channel. By allowing the entries in the lookup table to be modified, the resulting lookup table equalizer can not only perform transmit equalization, but also systematic jitter correction and jitter injection. FIG. 4B shows an example circuit implementation of a lookup table equalizer for transmit equalization, systematic jitter correction, and jitter injection. This example circuit implementation is similar to the one shown in FIG. 3B except that storage device 430 here contains a modifiable lookup table.

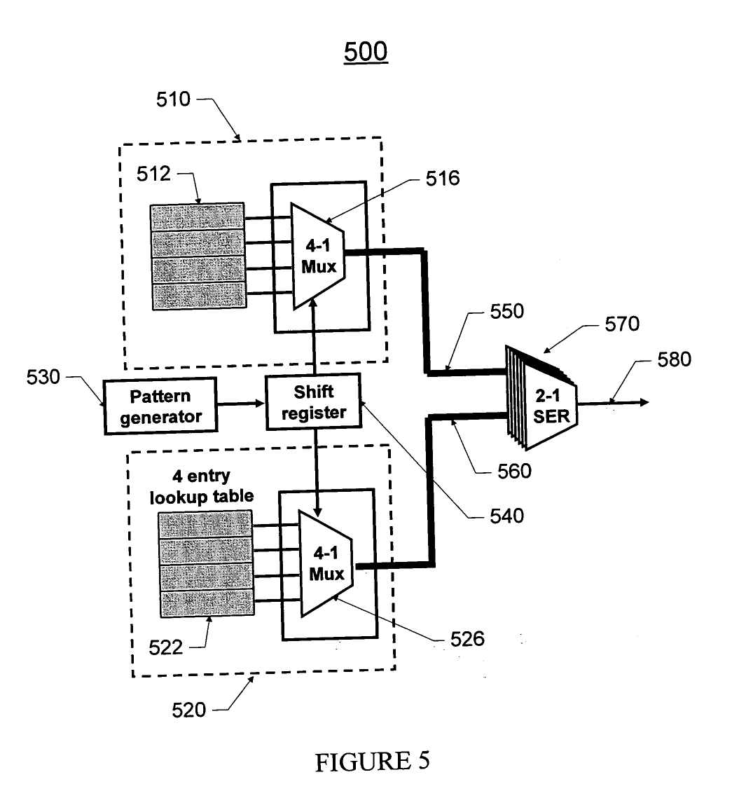

FIG. 5 shows an example two-way interleaving lookup table equalizer 500 for transmit equalization, systematic jitter correction, and jitter injection. Equalizer 500 includes a first interleaved section 510, a second interleaved section 520, a pattern generator 530, a shift register 540, and a serializer 570. Pattern generator 530 accepts an input data stream (not shown in the figure) at a bit rate x bps and produces two sub-streams each having a bit rate of x/2 bps by down-sampling the input data stream. For example, the first sub-stream would include bits 0, 2, 4, 6, 8, . . . of the input data stream, while the second sub-stream would include bits 1, 3, 5, 7, 9, . . . of the input data stream.

Either the first interleaved section 510 or the second interleaved section 520 is a 2-tap lookup table equalizer having a 4-entry lookup table. Like the equalizer shown in FIG. 4B, the first interleaved section 510 has a storage device 512 storing a 4-entry lookup table and a 4-1 multiplexer 516. Similarly, the second interleaved section 520 has a storage device 522 storing a 4-entry lookup table and a 4-1 multiplexer 526. Each section accepts one sub-stream and produces an equalized signal. For example, the first interleaved section 510 may accept the first sub-stream and produce a corresponding equalized signal 550; and the second interleaved section 520 may accept the second sub-stream and produce a corresponding equalized signal 560.

Shift register 540 performs functions similar to delay logic such as 350 as shown in FIG. 3B and FIG. 4B. The shift register delays by one cycle every input bit of both the first sub-stream and the second sub-stream produced by pattern generator 530. The outputs of the shift register are used to help multiplexers in each interleaved section (e.g., 516 and 526) to select one entry from the lookup table at one time.

Serializer 570 merges equalized signals (550 and 560) from the first interleaved section and the second interleaved section to produce a final equalized signal 580 for the input data stream. The final equalized signal 580 has the same bit rate (i.e., ×bps) as the input data stream. By using two interleaved sections, equalizer 500 is able to perform equalization for a high bit rate data stream with lower-speed and cheaper sub-equalizers (i.e., interleaved sections).

For each interleaved section (i.e., 510 and 520), entries in its lookup table may be modified for the purpose of systematic jitter correction and/or jitter injection for testing and characterization of the channel. In one embodiment, each interleaved section may share a single lookup table. In another embodiment, each interleaved section may have its own dedicated lookup table. In reality, a serializer may introduce jitters and/or other distortions to the final signal, interleaved sections each having its own dedicated lookup table may help to reduce and/or eliminate such jitters and/or other distortions.

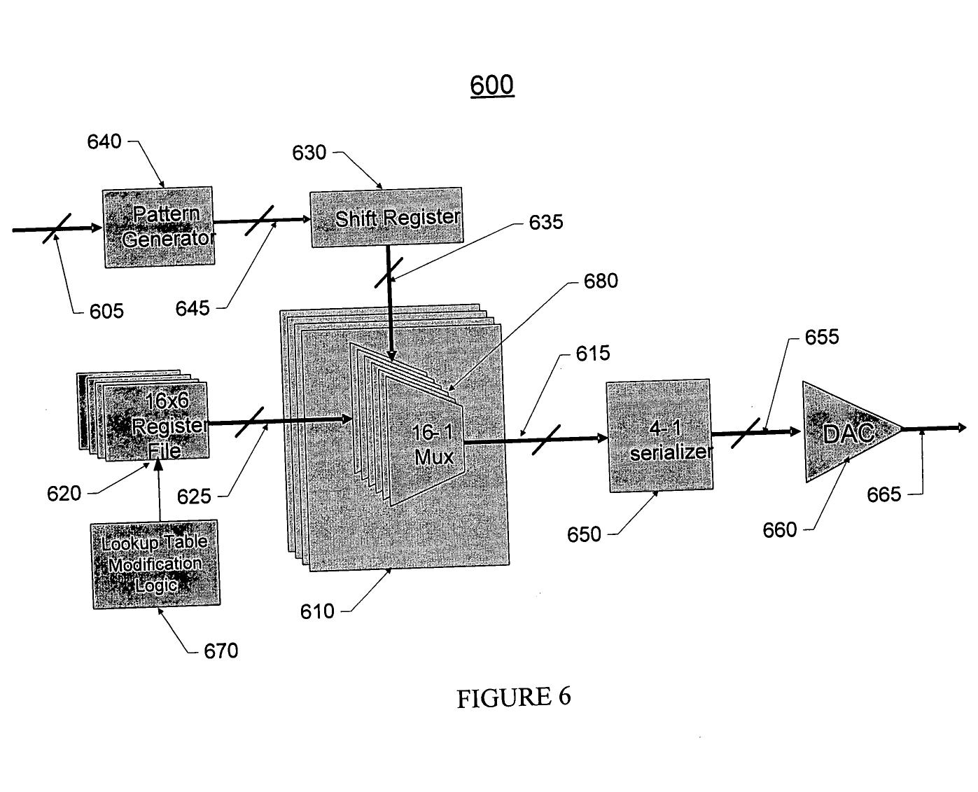

FIG. 6 shows an example four-way interleaving equalization system 600 for transmit equalization, systematic jitter correction, and jitter injection. Equalizer 600 includes a pattern generator 640, a shift register 630, a lookup table based equalizer 610, a register file 620, a serializer 650, and a D/A converter (“DAC”) 660. Pattern generator 640 accepts an input digital data stream 605 and produces four sub-streams 645 by down-sampling the input data stream 605. For example, the first sub-stream would include bits 0, 4, 8, 12, . . . of the input data stream; the second sub-stream would include bits 1, 5, 9, 13, . . . of the input data stream; the third sub-stream would include bits 2, 6, 10, 14, . . . of the input data stream; and the fourth sub-stream would include bits 3, 7, 11, 15, . . . of the input data stream. The bit rate of each sub-stream is one fourth of the bit rate of the input data stream.

Lookup table based equalizer 610 includes four interleaved sections with each section being a 4-tap lookup table equalizer. For a 4-tap lookup table equalizer, the corresponding lookup table has 16 entries covering all 16 possible outputs for any 4 bit combinations. If each interleaved section has 6 bits of output resolution, each lookup table will have 16 entries with each entry storing 6 bit data, i.e., the size of a lookup table is 16×6 bits. Each interleaved section has a 16-1 multiplexer (e.g., multiplexer 680) to select one out of 16 entries in a corresponding lookup table as the output at each clock cycle. Each interleaved section works on a sub-stream produced by the pattern generator 640 and produces an equalized output signal for that sub-stream.

Shift register 630 performs shift functions for each sub-stream produced by pattern generator 640. Because each interleaved section is a 4-tap equalizer, the shift register shifts each bit by up to 3 bits. For example, at time t, the current bit b(t), and other three previous bits, b(t-1), b(t-2), and b(t-3) of a sub-stream, together, enable a multiplexer in a corresponding interleaved section to select one entry from its lookup table as the output of the section.

Serializer 650 merges outputs 615 from all the four interleaved sections into one final equalized signal 655 for the input digital data stream. DAC 660 is optional and it converts the output signal 655 from the serializer from a digital form to an analog form. If input data stream 605 has a bit rate of 20 gb/s (Giga bits per second), for example, output 645 of the pattern generator will include 4 sub-streams each having a bit rate of 5 gb/s. Output 635 of the shift register will include 4×4 streams of data each having a bit rate of 5 gb/s since the shift register each bit by up to 3 bits and thus produces 4 sub-sub streams for each sub-stream. Output 615 from all the four interleaved sections will include 4×6 streams of data each having a bit rate of 5 gb/s because the output for each bit of an input sub-stream has a resolution of 6 bits. Output 655 of the serializer will include 6 streams of data each having a bit rate of 20 gb/s.

For each interleaved section, entries in its lookup table may be modified by lookup table modification logic 670 for the purpose of systematic jitter correction and/or jitter injection for testing and characterization of the channel. In one embodiment, each interleaved section may share a single lookup table. In another embodiment, each interleaved section may have its own dedicated lookup table. Since a serializer may introduce jitters and/or other distortions to output 655, interleaved sections each having its own dedicated lookup table may help to reduce and/or eliminate such jitters and/or other distortions.

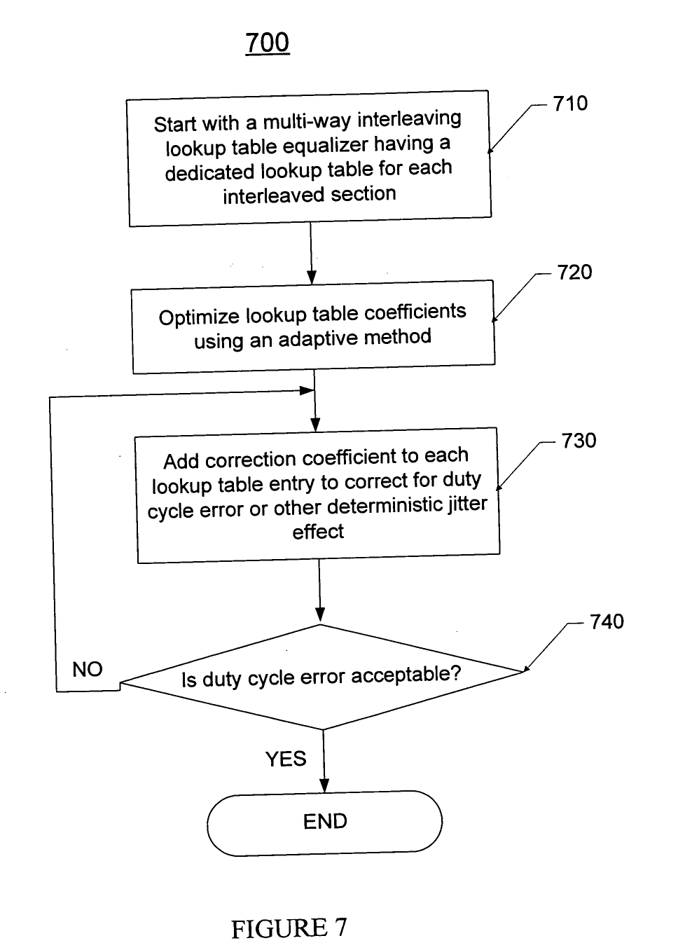

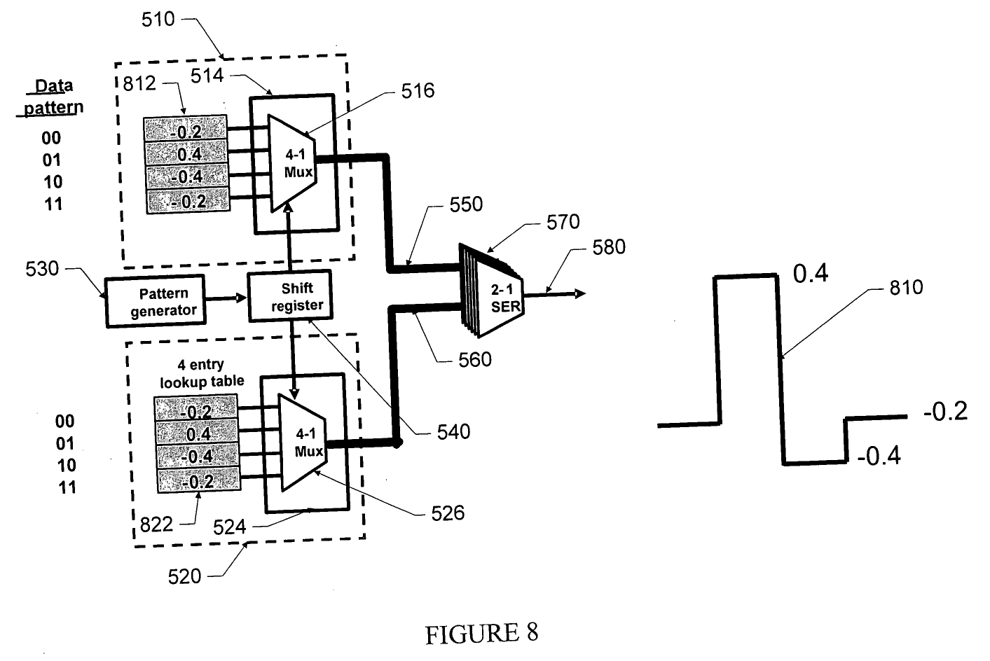

FIG. 7 is a flowchart illustrating an example process 700 for systematic jitter correction using a lookup table equalizer. Process 700 starts at block 710 with a multi-way interleaving lookup table equalizer having a dedicated lookup table for each interleaved section. At block 720, an adaptive method may be used to determine and optimize lookup table coefficients (entries). For example, a conditional update sign-sign LMS method as disclosed in U.S. patent application Ser. No. 10/660,228, filed on Sep. 10, 2003, which has been incorporated by reference into this specification earlier. FIG. 8 shows example lookup tables (i.e., lookup tables 812 and 822) with entry values obtained by using an adaptive method in a two-way interleaving lookup table equalizer. As a result of the adaptation, two lookup tables may have the same entries. The pulse response 810 of the resulting equalizer is also shown in FIG. 8.

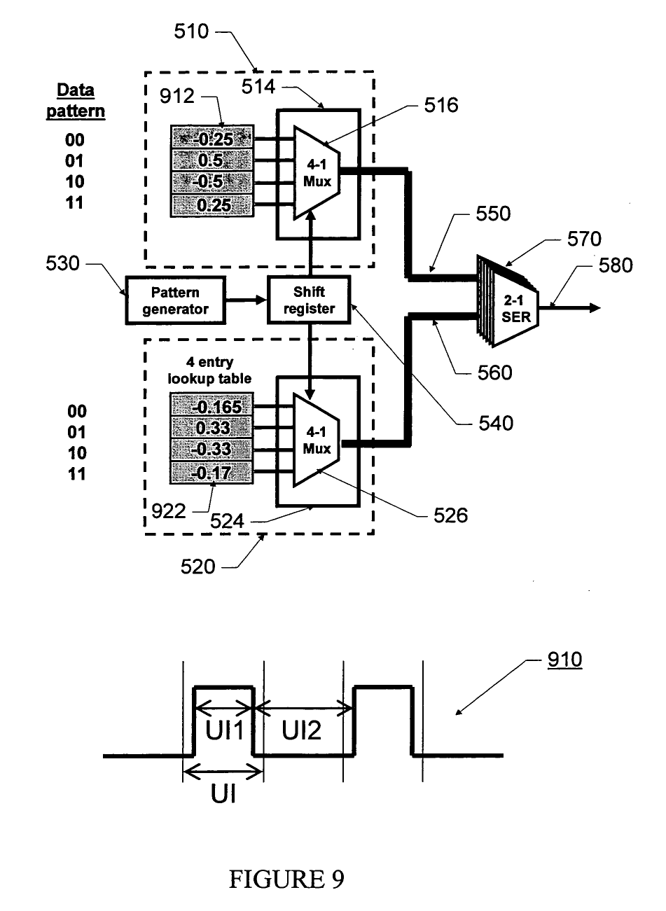

At block 730, a correction coefficient may be added to each lookup table entry to correct for systematic jitters, which may be represented at least partly by duty cycle errors. FIG. 9 shows one example of modifying entries in lookup tables of a two-way interleaving lookup table equalizer to correct for systematic jitters. Waveform 910 shows a signal actually received at the receiver. Because of systematic jitters caused by channel distortions and other system imperfections, errors in duty cycles may be present in the received signal. As shown in waveform 910, the actual width of 1's becomes UI1 and actual width of 0's becomes UI2 while the correct width for 1's or 0's should be UI (unit interval).

Duty cycle errors in the received signals may be used as a basis to correct/modify entries in lookup tables (i.e., lookup tables 812 and 822 in FIG. 8). In one embodiment, entries in lookup tables 812 and 822 may be modified according to Equations (1) and (2), respectively, as shown in the following:
Adjustment for coefficient=(Current coefficient−UI)/UI1; (1)
Adjustment for coefficient=(Current Coefficient−UI)/UI2. (2)
For example, assume that UI=100 ps, UI1=80 ps, and UI2=120 ps, entries in lookup tables 812 and 822 in FIG. 8 may be updated with a new value for each entry using Equations (1) and (2), respectively. The updated lookup tables 812 and 822 are shown as lookup table 912 and 922, respectively, in FIG. 9. In another embodiment, other methods (e.g., trial and error) may be used to modify lookup table coefficients based on received signals.

At block 740, a signal may be sent to the receiver through the two-way interleaving equalizer with updated lookup tables and the signal received at the receiver may be monitored. If duty cycle errors are still present in the received signal and are above a predetermined acceptable level, modification processing for lookup table entries in block 730 may be repeated until the duty cycle errors in the received signal have been reduced to the acceptable level. In one embodiment, if the duty cycle errors in the received signal are not acceptable, a different modification method may be used to update entries in lookup tables.

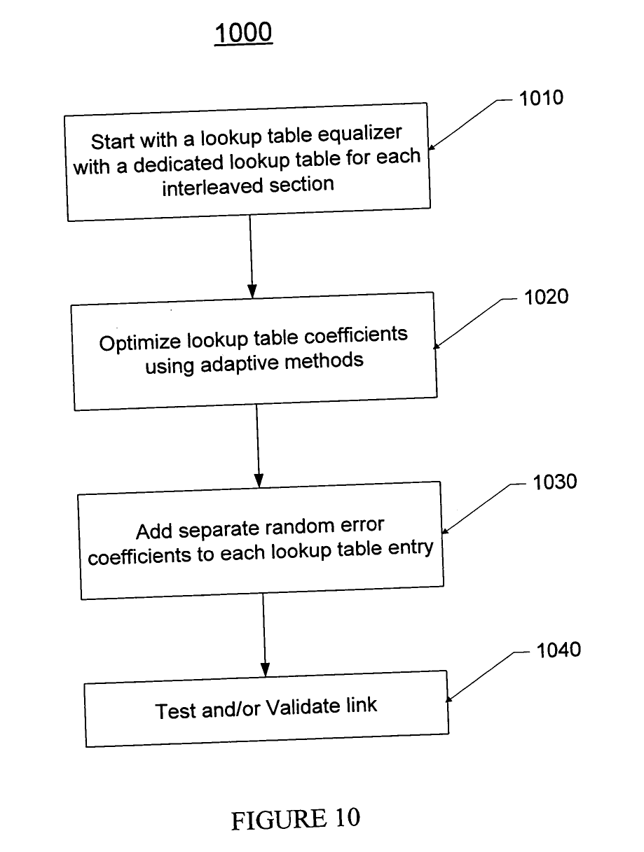

FIG. 10 is a flowchart illustrating an example process 1000 for jitter injection based testing and characterization of a channel. Process 1000 starts at block 1010 with a multi-way interleaving lookup table equalizer having a dedicated lookup table for each interleaved section. At block 1020, an adaptive method may be used to determine and optimize lookup table coefficients (entries). For example, a conditional update sign-sign LMS method as disclosed in U.S. patent application Ser. No. 10/660,228, filed on Sep. 10, 2003, which has been incorporated by reference into this specification earlier. Example lookup tables after the adaptive training for a two-way interleaving lookup table equalizer is shown in FIG. 8.

At block 1030, a random error coefficient may be added to each lookup table entry in the multi-way interleaving lookup table equalizer. Error coefficients added to the same entry of different lookup tables may be different. Such random error coefficients added to lookup table entries will be converted to both amplitude and phase modulation across a lossy channel. In this sense, jitters are injected into the channel. At block 1040, the channel may be tested/validated by sending a trial signal from the transmitter have the multi-way interleaving equalizer with random errors being added to lookup table entries, and examining the signal received at the receiver. Processing at block 1030 and 1040 may be repeated until the characteristics of the channel are identified.

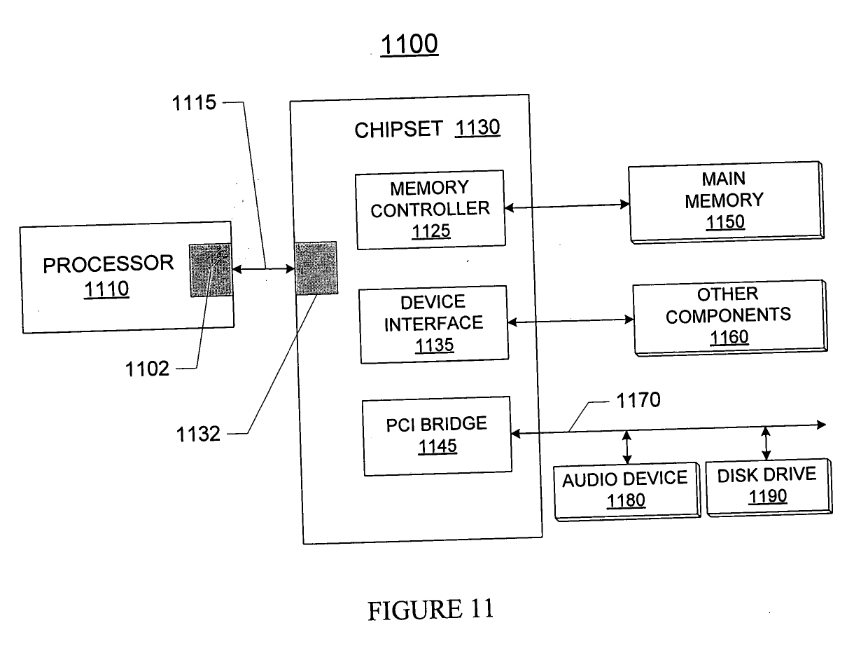

FIG. 11 is a block diagram of a computer system 1100 with at least one lookup table equalizer for transmit equalization, system jitter correction, and jitter injection. Computing system 1100 may comprise one or more processors 1110 coupled to a system interconnect 1115. Each processor may further include one or more processing cores. The computing system 1100 may also include a chipset 1130 coupled to the system interconnect 1115. Chipset 1130 may include one or more integrated circuit packages or chips. Chipset 1130 may comprise one or more device interfaces 1135 to support data transfers to and/or from other components 1160 of the computing system 1100 such as, for example, BIOS firmware, keyboards, mice, storage devices, network interfaces, etc. Chipset 1130 may be coupled to a Peripheral Component Interconnect (PCI) bus 1170. Chipset 1130 may include a PCI bridge 1145 that provides an interface to the PCI bus 1170. The PCI Bridge 1145 may provide a data path between the processor 1110 as well as other components 1160, and peripheral devices such as, for example, an audio device 1180 and a disk drive 1190. Although not shown, other devices may also be coupled to the PCI bus 1170.

Additionally, chipset 1130 may comprise a memory controller 1125 that is coupled to a main memory 1150. The main memory 1150 may store data and sequences of instructions that are executed by the processor 1110 or any other device included in the system. The memory controller 1125 may access the main memory 1150 in response to memory transactions associated with the processor 1110, and other devices in the computing system 1100. In one embodiment, memory controller 1150 may be located in processor 1110 or some other circuitries. The main memory 1150 may comprise various memory devices that provide addressable storage locations which the memory controller 1125 may read data from and/or write data to. The main memory 1150 may comprise one or more different types of memory devices such as Dynamic Random Access Memory (DRAM) devices, Synchronous DRAM (SDRAM) devices, Double Data Rate (DDR) SDRAM devices, or other memory devices.

Communications between different circuits in computing system 1100 are typically conducted over different channels which may cause distortions such as ISI. Each circuit in computing system 1100 may be both a receiver and a transmitter. Thus, at least some circuits may include one or more lookup table equalizers for transmit equalization, systematic jitter correction, and jitter injection. For example, the processor may include such an equalizer 1102 and the chipset 1130 may also include a similar equalizer 1132. Equalizer 1102 and/or equalizer 1132 may have multiple interleaved sections each having a lookup table. Coefficients of each lookup table may be modified based on signals received at the receiver to correct system jitters. Additionally, random errors may be added to teach lookup table to test and validate the channel.

Although an example embodiment of the disclosed subject matter is described with reference to block and flow diagrams in FIGS. 1-11, persons of ordinary skill in the art will readily appreciate that many other methods of implementing the disclosed subject matter may alternatively be used. For example, the order of execution of the blocks in flow diagrams may be changed, and/or some of the blocks in block/flow diagrams described may be changed, eliminated, or combined.

In the preceding description, various aspects of the disclosed subject matter have been described. For purposes of explanation, specific numbers, systems and configurations were set forth in order to provide a thorough understanding of the subject matter. However, it is apparent to one skilled in the art having the benefit of this disclosure that the subject matter may be practiced without the specific details. In other instances, well-known features, components, or modules were omitted, simplified, combined, or split in order not to obscure the disclosed subject matter.

While the disclosed subject matter has been described with reference to illustrative embodiments, this description is not intended to be construed in a limiting sense. Various modifications of the illustrative embodiments, as well as other embodiments of the subject matter, which are apparent to persons skilled in the art to which the disclosed subject matter pertains are deemed to lie within the scope of the disclosed subject matter.

What is claimed is:

1. A method for using an equalizer to correct systematic jitters in a digital system, comprising:
initializing said equalizer, said equalizer having a lookup table;
optimizing entries in said lookup table;
modifying entries in said lookup table; and
using said equalizer with said lookup table having said modified entries to correct said systematic jitters.

2. The method of claim 1, wherein said equalizer resides in a transmitter in said digital system, said equalizer having a plurality of interleaved sections with each interleaved section having a dedicated lookup table.

3. The method of claim 2, wherein optimizing entries in said lookup table comprises optimizing entries of each lookup table in each interleaved section using a conditional update sign-sign least mean square adaptation approach.

4. The method of claim 3, wherein modifying entries in said lookup table comprises:
transmitting a signal from said transmitter to a receiver via a channel in said digital system;
identifying errors in said signal when said signal is received by said receiver; and
adding adjustment coefficients to lookup table entries of each lookup table in each interleaved section based at least in part on said identified errors.

5. The method of claim 4, wherein transmitting a signal from said transmitter to a receiver comprises processing said signal by said equalizer with said optimized entries in each lookup table.

6. The method of claim 4, wherein modifying entries in said lookup table comprises applying a different modification scheme to each lookup table in each interleaved section.

7. The method of claim 1, further comprising
sending a signal from a transmitter to a receiver in said digital system after modifying entries in said lookup table, said transmitter including said equalizer, and said signal being processed by said equalizer;
measuring systematic jitters through said signal when said signal is received by said receiver; and
determining whether said systematic jitters are reduced to a predetermined level after modifying, and if not, repeating modifying entries in said lookup table until said systematic jitters are reduced to said predetermined level.

8. A method for using an equalizer to test at least one of a channel or a receiver in a digital system, comprising:
initializing said equalizer, said equalizer having a lookup table;
optimizing entries for said lookup table;
adding an error value to each lookup table entry of said lookup table; and
testing at least one of said channel or said receiver using said equalizer with said lookup table.

9. The method of claim 8, wherein said equalizer resides in a transmitter in said digital system, said equalizer having a plurality of interleaved sections with each interleaved section having a dedicated lookup table.

10. The method of claim 9, wherein optimizing entries in said lookup table comprises optimizing entries of each lookup table in each interleaved section using a conditional update sign-sign least mean square adaptation approach.

11. The method of claim 10, wherein testing at least one of said channel or said receiver comprises:
transmitting a signal from said transmitter to said receiver over said channel, said signal being processed by said equalizer with said optimized entries in each lookup table;
identifying distortions in said signal when said signal is received by said receiver, said identified distortions including both magnitude and phase distortions; and
characterizing at least one of said channel or said receiver based on said identified distortions.

12. The method of claim 10, wherein adding an error value to each lookup table entry of each lookup table in each interleaved section comprises applying a different error-adding pattern to each lookup table.

13. A circuit, comprising:
a lookup table equalizer to receive a bit stream signal and to process said bit stream signal, said equalizer including:
a pattern generator to produce at least one sub-stream from said bit stream signal;
at least one interleaved section, each section having a dedicated lookup table and each section processing one of said at least one sub-stream to produce an equalized sub-stream;
a storage device to store at least one lookup table for said at least one interleaved section; and
lookup table modification logic to modify entries in each lookup table for at least one of systematic jitter correction or jitter injection.

14. The circuit of claim 13, wherein said equalizer further comprises a shift register to perform delay functions for each of said at least one sub-stream.

15. The circuit of claim 13, wherein said equalizer further comprises a serializer to merge each equalized sub-stream produced by each interleaved section to produce an equalized signal for said bit stream signal.

16. The circuit of claim 15, wherein said equalizer further comprises a digital-to-analog converter to convert said equalized signal to an analog signal.

17. The circuit of claim 13, wherein said lookup table logic applies a different modification scheme for each lookup table for systematic jitter correction based on systematic jitters detected from signals received by a receiver, said signals being processed by said equalizer and being transmitted over a channel to a receiver.

18. The circuit of claim 13, wherein said lookup table logic adds an error value to each lookup table entry in a lookup table to inject jitters into a channel for testing and characterization of at least one of said channel or a receiver, said lookup table logic applying a different error-adding scheme to each lookup table.

19. A computing system, comprising:
synchronous dynamic random access memory (“SDRAM”); and
a processor coupled to access said SDRAM, said processor having a lookup table equalizer to receive a bit stream signal and to process said bit stream signal, said equalizer including:
a pattern generator to produce at least one sub-stream from said bit stream signal;
at least one interleaved section, each section having a dedicated lookup table and each section processing one of said at least one sub-stream to produce an equalized sub-stream;
a storage device to store at least one lookup table for said at least one interleaved section; and
lookup table modification logic to modify entries in each lookup table for at least one of systematic jitter correction or jitter injection.

20. The computing system of claim 19, wherein said equalizer further comprises:
a shift register to perform delay functions for each of said at least one sub-stream;
a serializer to merge each equalized sub-stream produced by each interleaved section to produce an equalized signal for said bit stream signal; and
a digital-to-analog converter to convert said equalized signal to an analog signal.

21. The computing system of claim 19, wherein said lookup table logic applies a different modification scheme for each lookup table for systematic jitter correction based on systematic jitters detected from signals received by a receiver, said signals being processed by said equalizer and being transmitted over a channel.

22. The computing system of claim 19, wherein said lookup table logic adds an error value to each lookup table entry in a lookup table to inject jitters into a channel for testing and characterization of at least one of said channel or a receiver, said lookup table logic applying a different error-adding scheme to each lookup table.
